(19) United States
(12) Patent Application Publication
(10) Pub. No.: US 2005/0218448 A1
(43) Pub. Date: Oct. 6, 2005

(54) Transistor structure having an oxidation inhibition layer and method of forming the same

(76) Inventors: Dae-Ik Kim, Gyeonggi-do (KR); Joon-Mo Kwon, Gyeonggi-do (KR); Byung-Hak Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/083,457

(22) Filed: Mar. 18, 2005

(30) Foreign Application Priority Data
Mar. 18, 2004 (KR) 2004-18325

(51) Int. Cl. H01L 27/108

(52) U.S. Cl. 257/333

(57) ABSTRACT

A transistor structure and a method of forming the same prevent a boundary face of first and second gate electrodes from being oxidized in a subsequent oxidation process, by forming an oxidation inhibition layer in the boundary face. A gate insulation layer is formed on a semiconductor substrate, and a gate stack is obtained by a sequential accumulation of first and second gate electrodes and a capping layer on the gate insulation layer. An oxidation inhibition layer is formed in a sidewall portion of the gate stack, and the oxidation inhibition layer covers a boundary face of the first and second gate electrodes. Source/drain regions are opposite to the gate stack.

### CROSS REFERENCE TO RELATED APPLICATIONS

This application claims priority from Korean Patent Application No. 2004-18325, filed on 18 Mar. 2004, the content of which is hereby incorporated by reference for all purposes.

### BACKGROUND OF THE INVENTION

1. Field of the Invention

This disclosure relates to semiconductor devices, and more particularly, to a transistor structure and a forming method thereof.

2. Description of the Related Art

Recently, the desire for semiconductor devices having lower power consumption and higher capacitance has brought about higher integration and higher-speed of the devices. Hence, a design rule is continuously reduced to integrate more semiconductor devices within a semiconductor chip of a limited size, which reduces an interval between gates and a length of a gate or a word line. The reduced interval between gates may cause a short channel effect and a leakage current. The reduced length of a gate may increase a gate resistance and decrease a device speed.

To counteract the reduction in device speed, research has been being vigorously pursued to reduce a gate resistance by forming the gate of a metal material having small resistance characteristics.

FIG. 1 is a sectional view of a transistor structure according to the conventional art.

Referring to FIG. 1, a gate oxide layer 104 is formed on a semiconductor substrate 100 where an active region and a non-active region are defined by a shallow trench insulator 102. On the gate oxide layer, a first gate electrode 106, a second gate electrode 108, and a capping layer 110 are sequentially accumulated, thus forming a gate stack. Then, an oxidation process of growing the gate oxide layer is pursued and then a gate spacer 112 and source/drain regions 114 and 116 are formed.

According to the conventional art, a tungsten layer may be used as a gate electrode to increase a device speed, thereby reducing a resistance of gate line. However, when a second gate electrode is formed of a tungsten material, a boundary face between a polysilicon layer used as a first gate electrode and the tungsten layer used as a second gate electrode may be oxidized in a subsequent oxidation process that occurs after forming the gate stack, thus causing a barrier layer formation problem. In other words, the boundary resistance increases, thereby reducing the device speed.

Embodiments of the invention address these and other disadvantages of the conventional art.

### SUMMARY OF THE INVENTION

Some embodiments of the invention provide a transistor structure and a method of forming the same, for use in a semiconductor device. A boundary face of first and second gate electrodes is prevented from being oxidized, and a boundary resistance therebetween is substantially reduced. Furthermore, the reduction of boundary resistance enhances a device speed.

### BRIEF DESCRIPTION OF THE DRAWINGS

The above and other features of exemplary embodiments of the invention will become readily apparent from the description that follows, with reference to the attached drawings in which:

FIG. 1 is a sectional view illustrating a transistor structure for use in a semiconductor device and a method of forming the same according to the conventional art; and

FIGS. 2 to 9 are sectional views illustrating sequential processes for a transistor structure and a method of forming the same in a semiconductor device according to some embodiments of the invention.

### DETAILED DESCRIPTION OF THE INVENTION

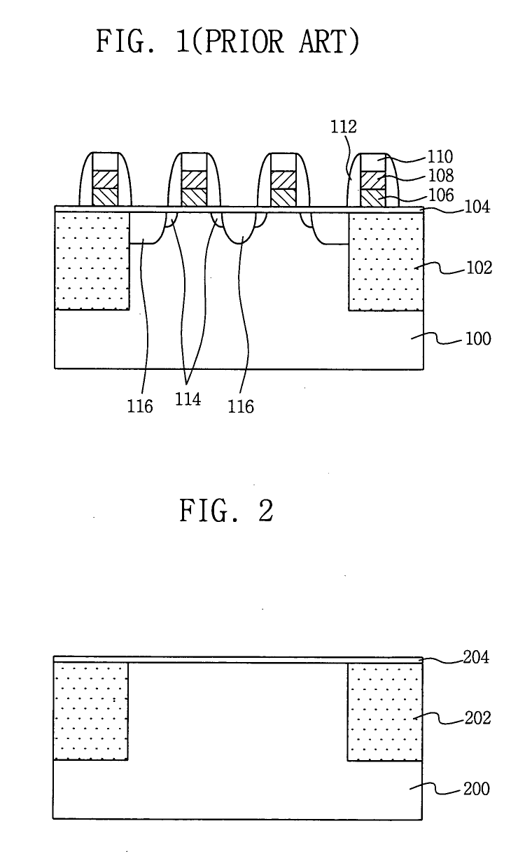

Some exemplary embodiments of the invention are more fully described in detail with reference to FIGS. 2 to 9. The invention may be embodied in many different forms and should not be construed as being limited to the exemplary embodiments set forth herein. Rather, these exemplary embodiments are provided so that this disclosure is thorough and complete, and to convey the concept of the invention to those skilled in the art.

FIGS. 2 to 9 are sectional views sequentially illustrating a transistor structure and a method of forming the same in a semiconductor device according to some embodiments of the invention.

Referring first to FIG. 2, a shallow trench insulator 202 is formed to define an active region and a non-active region on a predetermined region of a p-type semiconductor substrate 200.

The shallow trench insulator 202 is formed through processes of forming a trench having a given depth within a semiconductor substrate and then through a device isolation method such as an STI (Shallow Trench Isolation) process, etc. of depositing an insulation layer of oxide layer material. The shallow trench insulator 202 may be formed with a depth of about 2500 Å to 3000 Å. The shallow trench insulator 202 may be formed of any one among an oxide layer group composed of SOG (Spin On Glass), USG (Undoped Silicate Glass), BPSG (Boron Phosphorus Silicate Glass), PSG (Phosphor Silicate Glass), and PE-TEOS (Plasma Enhanced Tetra Ethyl Otho Silicate) reach flowable Oxide material. Alternatively, the shallow trench insulator 202 may consist of a multilayer that includes two or more members of the oxide layer group named above. Though not shown in the drawings, a p-type impurity, e.g., B ion, is ion implanted in the surface of the p-type semiconductor substrate 200, and then a thermal process is executed to form a p-type well region. The p-type impurity is ion implanted in an active region defined by the shallow trench insulator 202, to form a threshold voltage control region.

Subsequently, a gate insulation layer 204 is formed on the semiconductor substrate 200 having an active region and a non-active region. The gate insulation layer 204 is formed of oxide layer material, and may be formed by executing a thermal oxidation on the surface of the semiconductor substrate, and may be formed with a thickness of about 40 Å to 60 Å.

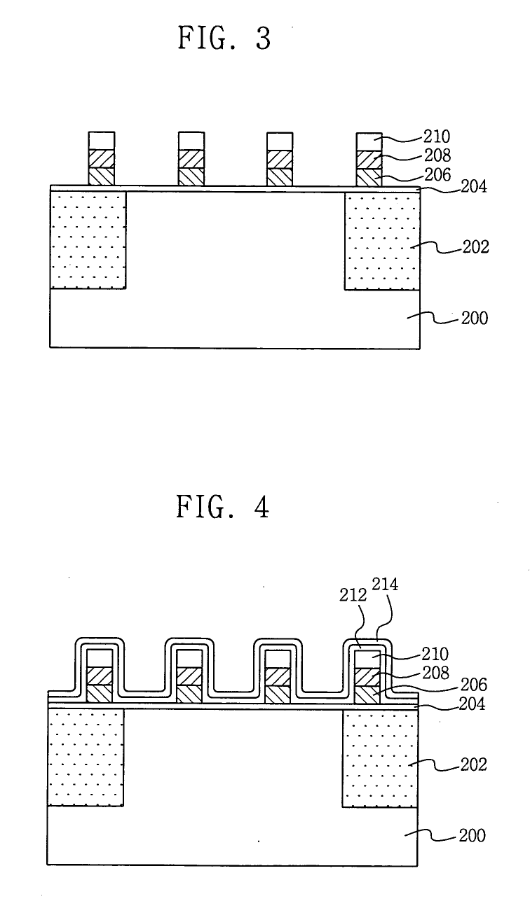

With reference to FIG. 3, a first gate electrode 206, a second gate electrode 208, and a capping layer 210 are sequentially formed on the gate insulation layer 204.

The first gate electrode 206 is formed of polysilicon material and serves as a buffering electrode that prevents pollution of the gate insulation layer, and may employ a chemical vapor deposition (CVD), a low-pressure chemical vapor deposition (LPCVD) or plasma chemical vapor deposition (PECVD), etc. as general deposition methods. The second gate electrode 208 may be formed of silicide material, but is preferably formed of tungsten (W) material to substantially reduce a resistance of the word line according to an exemplary embodiment of the invention, and may be formed through a general deposition method. The capping layer 210 may be formed of silicon nitride layer material having an etch selection rate for an interlayer dielectric of oxide layer material.

Next, a photoresist pattern (not shown) is formed on the capping layer 210, to expose a gate formation portion, and then the capping layer 210, the second gate electrode 208, and the first gate electrode 206 are sequentially etched to form a gate stack. The gate stack may be of a dual gate type that has two gates disposed in parallel on one active region, and it also may be of a line type that extends not only to the active region but also to the non-active region. Lengths and heights of the first gate electrode 206, the second gate electrode 208, and the capping layer 210 may be diversely designed and formed in conformity with a design rule. The photoresist pattern is removed through an ashing or stripping process.

Referring to FIG. 4, a first insulation layer 212 and a second insulation layer 214 are sequentially accumulated on the semiconductor substrate 200 that has the gate stack.

The first insulation layer 212 serves as an oxidation inhibition layer for preventing a boundary face of the first and second gate electrodes from being oxidized in a subsequent oxidation process, and may be formed of silicon nitride layer material that is capable of preventing the boundary face of the first and second gate electrodes from oxidizing. The first insulation layer 212 may be formed through a deposition method such as CVD, LPCVD, PECVD, SACVD (Semi-Atmospheric Chemical Vapor Deposition), a sputtering method, or atomic layer deposition, etc. The first insulation layer 212 may have a thickness of about 100 Å to 150 Å. The second insulation layer 214 may be formed of, e.g., a silicon oxide layer material having an etch selection rate which is different from the first insulation layer, and may be formed through a deposition method such as a CVD, a sputtering method, etc.

With reference to FIG. 5, an etching process is performed to remove the horizontally arranged portions of the second insulation layer 214. The etching process may be a dry etching such as a plasma dry etching process, etc.

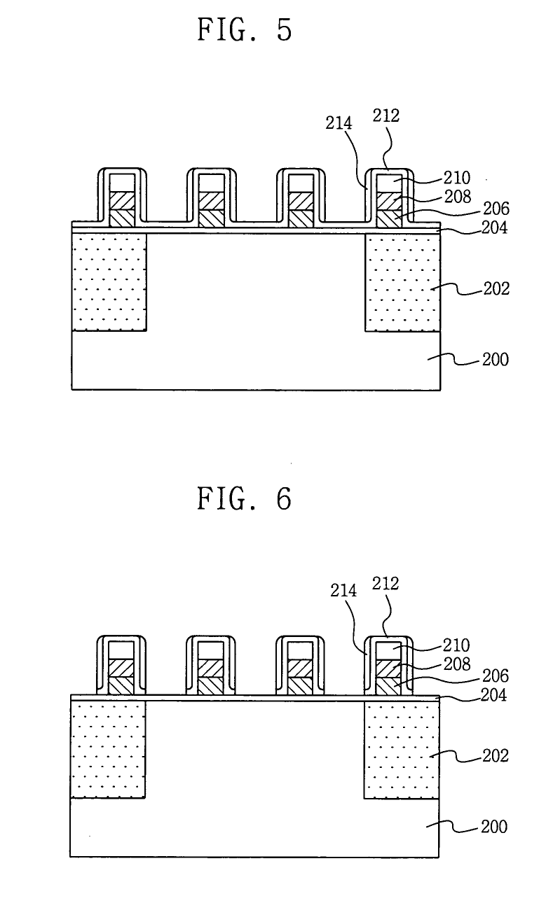

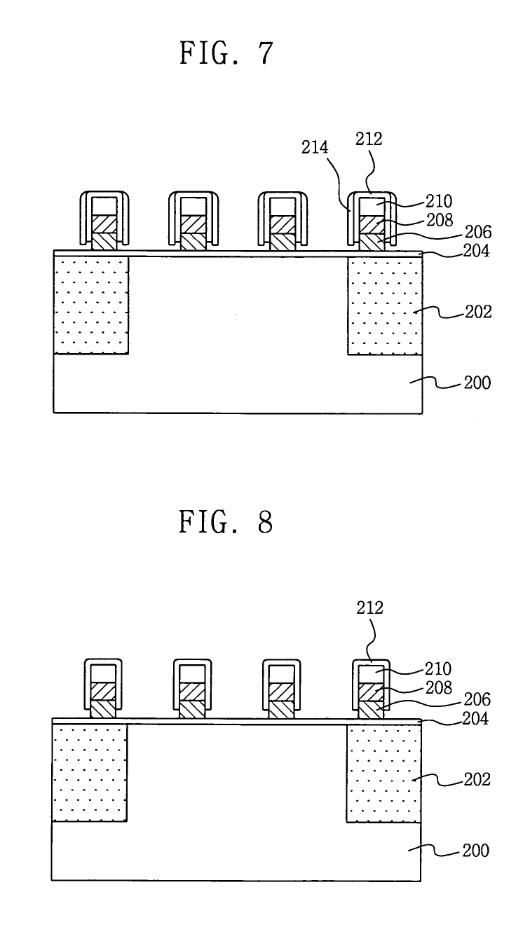

Referring to FIG. 6, an etching process is executed to remove the portions of the first insulation layer 212 that are formed horizontally on the gate insulation layer 204.

The etching process of the first insulation layer 212 is performed using an anisotropic etching process such as a dry etching, a plasma dry etching, etc. that uses the gate insulation layer 204 as an etch stop layer and exposes the gate insulation layer 204.

Then, with reference to FIG. 7, a portion of the first insulation layer 212 that is disposed in a position lower than a boundary face of the first and second gate electrodes is removed.

The first insulation layer 212 is etched to remove a portion of the first insulation layer disposed in a position lower than a boundary face of the first and second gate electrodes by using a wet etching employing etching solution. When the first insulation layer is formed of silicon nitride layer material, a wet etchant such as H₃PO₄ may be used. As a result, a lower portion of the first gate electrode 206 is exposed, and the first insulation 212 is left only on a sidewall portion of a gate stack so as to cover the boundary face of the first and second gate electrodes 206 and 208.

With reference to FIG. 8, the portion of the second insulation layer 214 that remains on the first insulation layer 212 is removed, thus a boundary face of the first and second gate electrodes 206 and 208 is covered in a sidewall of gate stack and the first insulation layer 212 is formed, exposing a lower portion of a first gate electrode 206. When the second insulation layer 214 is formed of a silicon oxide layer material, a wet etching using HF is performed to remove it. That is, the first insulation layer 212 is formed so as to cover the boundary face of the first and second gate electrodes, thereby being served as an oxidation inhibition layer that prevents a barrier layer influenced by a subsequent oxidation process from being formed on a boundary face of the first and second gate electrodes. Thus, a boundary resistance increase may be prevented in the subsequent oxidation process, remarkably increasing the speed of the device.

Next, an oxidation process for growing a gate insulation layer 204 under the gate stack is executed. The oxidation process remedies the damage generated by the etching process used to form the gate stack, enhances reliability of hot carriers, and reduces a gate induced drain leakage (GIDL), thus improving the refresh characteristics of the device. That is, the oxidation process is performed to improve operating characteristics of the semiconductor device.

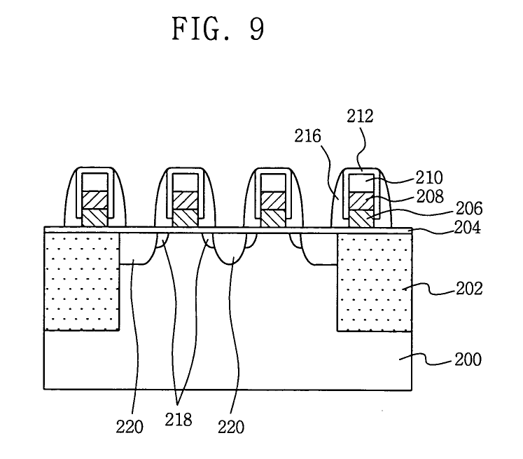

As shown in FIG. 9, a gate spacer 216 is formed on a sidewall of the exposed gate stack and on the first insulation layer 212, and then an n type-impurity, e.g., P (phosphorous) or As (arsenic), etc., is implanted with an energy of 20 KeV to 30 KeV, to a density of about 1.0×10¹³ to about 3.0×10¹⁵ ion atoms/cm², by using the gate spacer 216 as an ion implantation mask, to form n+type source/drain regions 220 of a high density. Also, before forming the gate spacer 216, n−type impurities of a relatively low density in comparison with the formation of the high density n+type source/drain is ion implanted by using the gate stack as an ion implantation mask, thus forming n−type source/drain regions 218. Then, high density n+type source/drain regions 220 having an impurity density that is higher than the low density n−type source/drain regions 218 may be formed on a portion of the low density n−type source/drain regions 218. In this case, source/drain regions 218 and 220 form an LDD (Lightly Doped Drain) structure.

As a result, as shown in FIG. 9, a transistor structure according to some embodiments of the invention includes a gate insulation layer 204 formed on a semiconductor substrate 200 on which an active region and a non-active region are defined by a shallow trench insulator 202, a gate stack obtained by a sequential accumulation of first and second gate electrodes 206 and 208 and a capping layer 210 on the gate insulation layer 204, an oxidation inhibition layer 212 formed in a sidewall portion of the gate stack, so as to cover a boundary face of the first and second gate electrodes 206 and 208 and to expose a lower portion of the first gate electrode 206, and source/drain regions 218 and 220 opposite to the gate stack. The structure may further include a gate spacer 216 formed on a sidewall of the gate stack and on a first insulation layer.

In a transistor structure and a method of forming the same according to an some embodiments of the invention, a specific oxidation inhibition layer is formed on a sidewall of gate stack, such that a boundary face of first and second gate electrodes that constitute the gate stack is covered and a lower portion of the second gate electrode is exposed, thereby preventing the boundary face of the first and second gate electrodes from being oxidized in a subsequent oxidation process. Hence, the boundary resistance of the first and second gate electrodes is reduced and a design rule is reduced, increasing the speed of the device.

As described above, according to some embodiments of the invention, a boundary face of first and second gate electrodes constituting a gate stack is covered, and an oxidation inhibition layer is formed in a sidewall of the gate stack so as to expose a lower portion of the second gate electrode, thereby preventing the boundary face of the first and second gate electrodes from being oxidized.

A boundary face of first and second gate electrodes is protected in an oxidation process, by forming an oxidation inhibition layer in a sidewall of a gate stack, thereby preventing or substantially reducing an increased boundary resistance of first and second gate electrodes and increasing a speed of semiconductor devices.

Embodiments of the invention may be practiced in many ways. What follows are exemplary, non-limiting descriptions of some of these embodiments.

An exemplary embodiment of the invention provides a transistor structure formed on a semiconductor substrate, for use in a semiconductor device. The structure includes a gate insulation layer formed on the semiconductor substrate, a gate stack obtained by a sequential accumulation of first and second gate electrodes and a capping layer on the gate insulation layer, an oxidation inhibition layer that is formed in a sidewall portion of the gate stack and that covers a boundary face of the first and second gate electrodes, and source/drain regions opposite to the gate stack.

The oxidation inhibition layer is formed in a sidewall portion of the gate stack so that a boundary face of the first and second gate electrodes is covered and a lower portion of the first gate electrode is exposed. The oxidation inhibition layer may be formed of silicon nitride layer material, and has a thickness of about 100 Å to 150 Å.

The structure further includes a shallow trench insulator defining an active region and a non-active region on a predetermined region of the semiconductor substrate, and further includes a gate spacer formed in a sidewall of the gate stack and on the oxidation inhibition layer.

According to another exemplary embodiment of the invention, a method of forming a transistor for use in a semiconductor device includes forming a gate insulation layer on a semiconductor substrate, forming a gate stack obtained by a sequential accumulation of first and second gate electrodes and a capping layer on the gate insulation layer, forming a first insulation layer in a gate sidewall portion so as to expose a lower portion of the second gate electrode and to cover a boundary face of the first and second gate electrodes, and forming source/drain regions opposite to the gate stack.

The forming of the first insulation layer includes sequentially forming first and second insulation layers in a sidewall of the gate stack, removing only the first insulation layer existing in a position lower than the boundary face of the first and second gate electrodes, and removing the second insulation layer.

The first insulation layer is an oxidation inhibition layer for preventing the boundary face of the first and second gate electrodes from being oxidized, and is formed of material having an etch selection rate which is different from an oxide layer, and is formed to a thickness of about 100 Å to 150 Å.

It will be apparent to those skilled in the art that modifications and variations can be made in the present invention without deviating from the spirit or scope of the invention. Thus, it is intended that the invention cover any such modifications and variations of this invention provided they come within the scope of the appended claims and their equivalents. For instance, first and second insulation layers are not limited to the material described above, but may be formed of insulation layers having other etch selection rates. Furthermore, a thickness of first and second insulation layers may be applied in conformity with various design rules. Accordingly, these and other changes and modifications are seen to be within the true spirit and scope of the invention as defined by the appended claims.

1. A transistor structure comprising:
a gate insulation layer formed on a semiconductor substrate;
a gate stack that includes a first gate electrode, a second gate electrode, and a capping layer that are sequentially formed on the gate insulation layer;
an oxidation inhibition layer formed on a sidewall portion of the gate stack, the oxidation inhibition layer covering a boundary face of the first and second gate electrodes; and
source/drain regions disposed on both sides of the gate stack.

2. The structure of claim 1, wherein the oxidation inhibition layer is disposed on a sidewall portion of the gate stack to cover a boundary face of the first and second gate electrodes and to expose a lower portion of the first gate electrode.

3. The structure of claim 1, wherein the oxidation inhibition layer consists of a silicon nitride layer material.

4. The structure of claim 1, wherein the oxidation inhibition layer is about 100 Å to 150 Å thick.

5. The structure of claim 1, further comprising a gate spacer disposed on a sidewall of the gate stack and on the oxidation inhibition layer.

6. The structure of claim 1, wherein the gate stack comprises a dual gate structure having two gates of a line type arranged in parallel on an active region.

7. The structure of claim 1, wherein the first gate electrode consists of a polysilicon material.

8. The structure of claim 1, wherein the second gate electrode consists of a tungsten material.

9. The structure of claim 1, further comprising a shallow trench insulator that defines an active region and a non-active region on a predetermined area of the semiconductor substrate.

10. The structure of claim 1, wherein the source/drain regions have a lightly doped drain (LDD) structure with a low-density source/drain region and a high-density source/drain region.

11. A method of forming a transistor comprising:
depositing a gate insulation layer on a semiconductor substrate;
sequentially stacking a first gate electrode, a second gate electrode, and a capping layer on the insulation layer to form a gate stack;
depositing a first insulation layer on a sidewall of the gate stack to expose a lower portion of the second gate electrode and to cover a boundary face of the first and second gate electrodes; and
forming source/drain regions to both sides of the gate stack.

12. The method of claim 11, wherein depositing the first insulation layer comprises:
sequentially depositing the first insulation layer on the sidewall of the gate stack and a second insulation layer on the first insulation layer;
removing a portion of the first insulation layer that is disposed below the boundary face of the first and second gate electrodes; and
removing the second insulation layer.

13. The method of claim 11, wherein depositing the first insulation layer comprises depositing an oxidation inhibition layer that prevents the boundary face of the first and second gate electrodes from being oxidized.

14. The method of claim 11, wherein depositing the first insulation layer comprises depositing a material having an etch selection rate of that is different from an oxide layer.

15. The method of claim 11, wherein depositing the first insulation layer comprises depositing a silicon nitride layer material.

16. The method of claim 11, wherein depositing the first insulation layer comprises depositing the first insulation layer to a thickness of about 100 Å to 150 Å.

17. The method of claim 12, wherein removing the portion of the first insulation layer comprises wet etching using an etchant solution.

18. The method of claim 12, wherein depositing the second insulation layer comprises depositing a silicon oxide layer material having an etch selection rate that is different from that of the first insulation layer.

19. The method of claim 11, further comprising, before depositing the gate insulation layer, defining an active region and a non-active region within the semiconductor substrate using a shallow trench insulator.

20. The method of claim 11, further comprising, after depositing the first insulation layer, forming a gate spacer on a sidewall of the exposed gate stack and on the first insulation layer.

21. The method of claim 1, wherein forming the source/drain regions comprises forming an LDD structure having a low-density source/drain region and a high-density source/drain region.
